(19) United States
(12) Patent Application Publication
(10) Pub. No.: US 2005/0250298 A1
(43) Pub. Date: Nov. 10, 2005

(54) In situ doped epitaxial films

(76) Inventor: Matthias Bauer, Riederich (DE)

Correspondence Address: KNOBBE MARTENS OLSON & BEAR LLP, 2040 MAIN STREET, FOURTEENTH FLOOR, IRVINE, CA, 92614, US

(21) Appl. No.: 11/113,829

(22) Filed: Apr. 25, 2005

Related U.S. Application Data
(60) Provisional application No. 60/565,033, filed on Apr. 23, 2004.
(60) Provisional application No. 60/565,909, filed on Apr. 27, 2004.

(51) Int. Cl. C30B 1/00; H01L 21/469; H01L 21/31; H01L 21/36; H01L 21/20

(52) U.S. Cl. 438/481

(57) ABSTRACT

A method for depositing an in situ doped epitaxial semiconductor layer comprises maintaining a pressure of greater than about 80 torr in a process chamber housing a patterned substrate. The method further comprises providing a flow of dichlorosilane to the process chamber. The method further comprises providing a flow of a dopant hydride to the process chamber. The method further comprises selectively depositing the epitaxial semiconductor layer on single crystal material on the patterned substrate at a rate of greater than about 3 nm min⁻¹.

### REFERENCE TO PRIORITY APPLICATIONS

This application claims the benefit of U.S. Provisional Patent Application 60/565,033 (filed 23 Apr. 2004) and U.S. Provisional Patent Application 60/565,909 (filed 27 Apr. 2004). The entire disclosure of both of these priority applications is hereby incorporated by reference herein.

### FIELD OF THE INVENTION

The present invention relates generally to selective epitaxial deposition, and more particularly to in situ rapid deposition of doped semiconductor layers.

### BACKGROUND OF THE INVENTION

Improvement of wafer throughput is a continuing challenge in the semiconductor industry, especially with respect to single wafer processing. In single wafer processing, individual wafers are processed sequentially in a single processing tool. Improved wafer throughput generally leads to reduced costs and improved operating margins.

One application in which increased wafer throughput is beneficial is in epitaxial deposition of semiconductor material-both doped (extrinsic) and undoped (intrinsic)—for forming integrated circuit devices. In certain applications, such epitaxial deposition takes place after other structures, such as field isolation regions, have already been formed. Blanket deposition on a patterned wafer, followed by photolithographic patterning and etching, generally requires expensive additional steps as compared to selective deposition on a patterned wafer. Specifically, selective epitaxial deposition is configurable to take place only upon exposed single-crystal semiconductor material on a patterned wafer, with surrounding insulators receiving little or no deposition. Therefore, use of selective deposition allows subsequent mask and etch steps to be avoided in certain applications, thereby increasing throughput. Likewise, for deposition of doped semiconductor material, use of in situ doping increases throughput in certain applications by allowing subsequent dopant implantation, diffusion and/or activation steps to be omitted.

### SUMMARY OF THE INVENTION

Disadvantageously, many selective deposition chemistries tend to produce slow deposition rates, such that some or all of the throughput gained by omitting photolithography and etch steps is lost due to the slower deposition rate. Likewise, many in situ doping chemistries also have reduced deposition rates, such that some or all of the throughput gained by performing the doping in situ is lost due to the slower deposition rate. Especially problematic is high concentration n-type doping, such as doping with high concentrations of arsenic or phosphorous. Using conventional techniques, it has been difficult or impossible to produce n-type doping levels above about 10¹⁹ cm⁻¹ with selective epitaxial growth performed using chemical vapor deposition processes at or above the reduced pressure chemical vapor deposition (“RPCVD”) and low pressure chemical vapor deposition (“LPCVD”) pressure regimes. Therefore, improved methods for performing selective epitaxial deposition of semiconductor materials, including in situ doped semiconductor materials have been developed.

According to one embodiment of the present invention, a method for depositing an in situ doped epitaxial semiconductor layer comprises maintaining a pressure of greater than about 80 torr in a process chamber housing a patterned substrate. The method further comprises providing a flow of dichlorosilane to the process chamber. The method further comprises providing a flow of a dopant hydride to the process chamber. The method further comprises selectively depositing the epitaxial semiconductor layer on single crystal material on the patterned substrate at a rate of greater than about 3 nm min⁻¹.

According to another embodiment of the present invention, a method of forming contacts for a transistor structure comprises providing a substrate having a defined source active area and a defined drain active area. The method further comprises exposing the source and drain active areas to a precursor mixture including dichlorosilane, a dopant hydride and an etchant gas. This results in selective deposition of an in situ doped epitaxial semiconductor layer on the source and drain active areas.

According to another embodiment of the present invention, a process for depositing silicon containing layers comprises providing a chamber at a pressure greater than about 100 torr. The process further comprises flowing dichlorosilane and an n-type dopant hydride over a substrate housed in the chamber. The process further comprises epitaxially depositing a silicon containing layer on the substrate at rate of greater than about 25 nm min⁻¹.

### BRIEF DESCRIPTION OF THE DRAWINGS

FIG. 1 is a graph illustrating growth rate, resistivity and dopant concentration as a function of hydrogen flow rate in an exemplary embodiment.

FIG. 2A is a graph illustrating arsenic concentration as a function of deposition temperature, AsH₃ flow rate, and film thickness for a first sample deposited film.

FIG. 2B is a graph illustrating arsenic concentration as a function of deposition temperature, AsH₃ flow rate, and film thickness for a second sample deposited film.

FIG. 3A is a graph illustrating growth rate as a function of temperature in an exemplary embodiment.

FIG. 3B is a graph illustrating arsenic concentration as a function of temperature in an exemplary embodiment.

FIG. 4A is a graph illustrating growth rate as a function of AsH₃ flow rate in an exemplary embodiment.

FIG. 4B is a graph illustrating arsenic concentration as a function of AsH₃ flow rate in an exemplary embodiment.

FIG. 5 is a graph illustrating growth rate and resistivity as a function of inverse temperature for various AsH₃ flow rates in an exemplary embodiment.

FIG. 6 is a graph illustrating growth rate as a function of inverse temperature for various dopants and dopant concentrations in an exemplary embodiment.

FIG. 7 is a graph illustrating growth rate and resistivity of a silicon film as a function of pressure in an exemplary embodiment.

FIG. 8 is a graph illustrating growth rate and germanium incorporation as a function of GeH₄ flow rate in an exemplary embodiment.

FIG. 9 is a graph illustrating growth rate as a function of GeH₄ flow rate for both non-doped (without AsH₃) and doped (with AsH₃) films in an exemplary embodiment.

FIG. 10 is a graph illustrating resistivity as a function of GeH₄ flow rate in an exemplary embodiment.

FIG. 11 is a graph illustrating growth rate and resistivity of a silicon germanium film as a function of pressure in an exemplary embodiment.

### DETAILED DESCRIPTION OF THE PREFERRED EMBODIMENT

Disclosed herein are exemplary embodiments of improved methods for performing selective epitaxial deposition of semiconductor materials, including in situ doped semiconductor materials. Exemplary semiconductor materials that are deposited using certain of the embodiments disclosed herein include silicon films and silicon germanium films. Certain of the chemical vapor deposition (“CVD”) techniques disclosed herein produce semiconductor films with improved crystal quality, improved electrical activation of incorporated dopants, and increased growth rate. In certain embodiments, highly doped selective deposition is possible under atmospheric conditions using dichlorosilane (“DCS”) as a silicon precursor, dopant hydrides, and optionally, HCl to improve selectivity. Germanium and/or carbon precursors, such as germane or methylsilane, are optionally added to the process gas mixture to form films that include germanium and/or carbon.

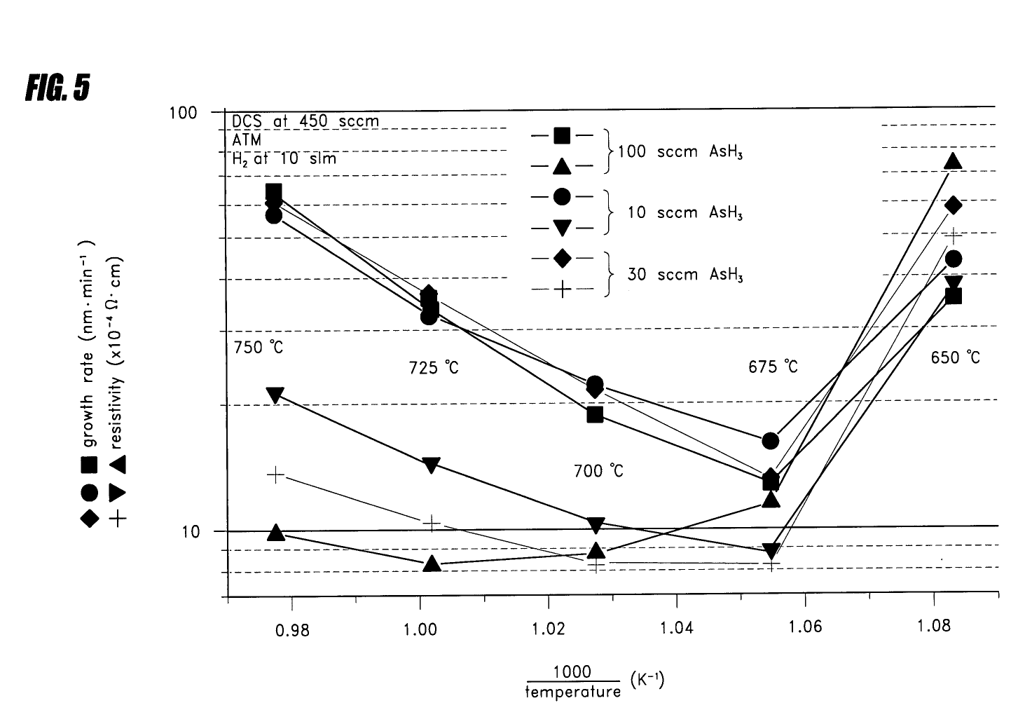

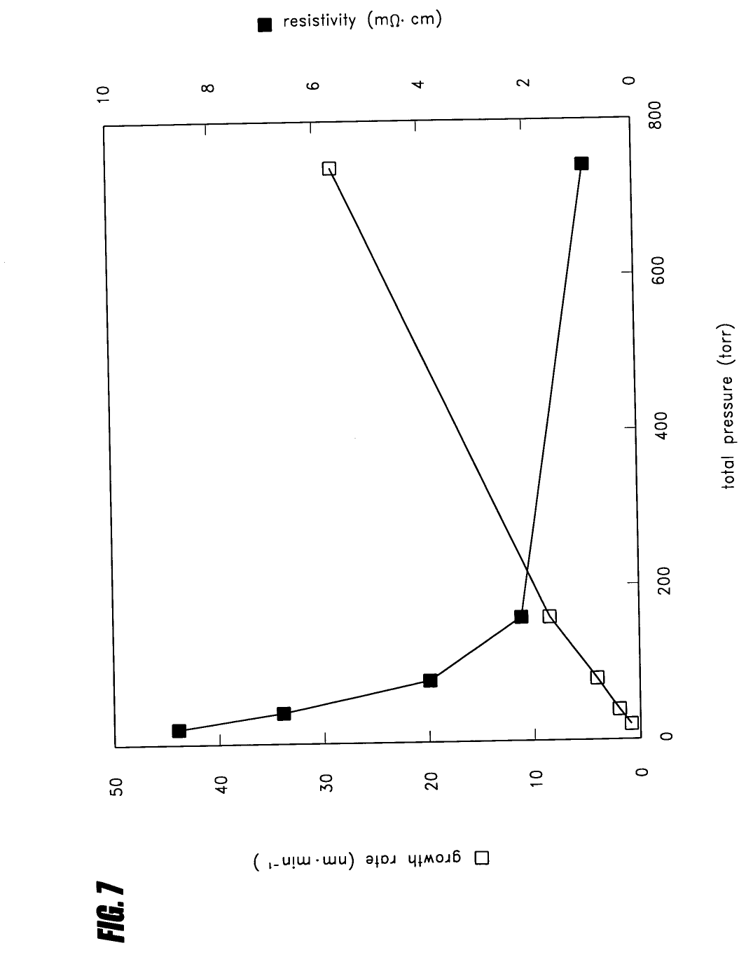

Deposition at pressures above the LPCVD and RPCVD pressure regimes, preferably greater than about 80 torr, more preferably greater than about 100 torr, and most preferably at atmospheric pressure, can be selective with both high dopant incorporation and high deposition rates. As indicated in FIG. 7, active dopant incorporation increases markedly with pressure. The data illustrated in FIG. 7 were obtained from an exemplary embodiment wherein a blanket layer of epitaxial silicon was grown on a 200 mm wafer at about 700° C. and with substantially no HCl flow. As illustrated, between approximately 10 torr and approximately 40 torr, films with as-deposited resistivity of about 3.0 mΩ·cm were obtained, whereas at pressures over about 100 torr, under otherwise similar conditions, films with as-deposited resistivity under about 1.0 m Ω·cm were obtained. In other embodiments, as illustrated in FIG. 5, silicon films with similar resistivity were grown at other temperatures, but with otherwise similar processing conditions. Specifically, in one embodiment a silicon film having resistivity 0.8 mΩ cm was grown at 700° C., and in another embodiment a silicon film having resistivity 1.3 mΩ cm was grown at 750° C.

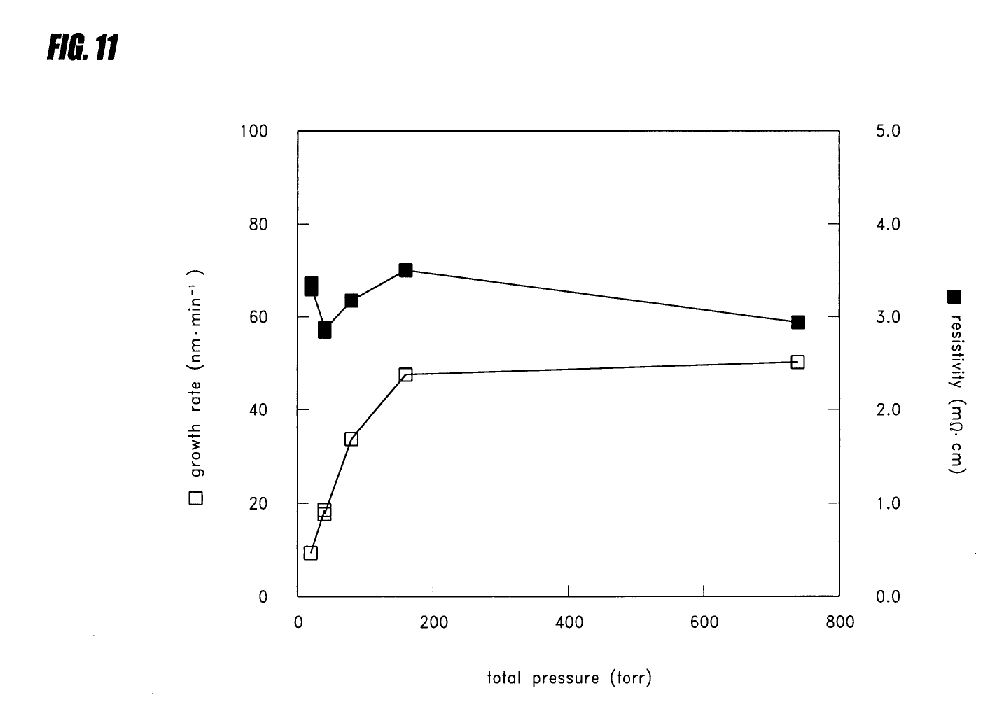

Similar results were obtained for silicon germanium deposition, as illustrated in FIG. 11. The data illustrated in FIG. 11 were obtained from an exemplary embodiment wherein a blanket layer of epitaxial silicon germanium was grown on a 200 mm wafer at about 730° C. and with substantially no HCl flow. As indicated in FIG. 11, for films with low resistivity—about 3 Ω·cm—the film resistivity is nearly independent of the pressure at which the film is grown for deposition at pressures greater than about 200 torr.

In a modified embodiment, the resistivity of a doped semiconductor film is further decreased by performing an anneal subsequent to deposition. For example, in one embodiment, a one minute anneal at about 900° C. reduces the resistivity of a silicon film from about 1.1 Ω·cm to about 0.88 Ω·cm. In another embodiment, a one minute anneal at about 1000° C. reduces the resistivity of a silicon film from about 1.1 Ω·cm to about 0.85 Ω·cm. In another embodiment, an spike anneal at 1050° C. reduces the resistivity of a silicon film from about 1.1 Ω·cm to about 0.93 Ω·cm. In another embodiment, a three second anneal at about 1050° C. reduces the resistivity of a silicon film from about 1.1 Ω·cm to about 0.86 Ω·cm. In certain embodiments the anneal is performed in situ, while in other embodiments the anneal is performed ex situ.

Conventionally, it was understood that increasing the flow rate for n-type dopant precursor gases relative to the flow rate for silane precursor gases would reduce deposition rates. However, in certain of the embodiments disclosed herein, the deposition rate can be increased, even if the flow rate for the dopant precursor gases relative are increased relative to the flow rate for the semiconductor precursor gases. Also disclosed herein are techniques for enhancing dopant incorporation while providing an increased flow of semiconductor precursor gases relative to flow of dopant precursor gases. Exemplary semiconductor precursor gases include silicon precursor gases, such as DCS, and germanium precursor gases, such as germane (GeH₄).

In an exemplary selective deposition embodiment, little or no deposition occurs over insulating materials such as silicon nitride based materials or silicon oxide based materials. In certain embodiments, selective deposition uses an etchant, such as HCl, and therefore selective deposition rates are generally depressed relative to non-selective deposition rates. For example, selective deposition rates are typically less than approximately 50 nm min⁻¹. For non-selective deposition, on the other hand, deposition rates are also less than 50 nm min⁻¹ in certain embodiments, although deposition rates are 50 nm min⁻¹ or higher in other embodiments wherein greater precursor flow rates are provided.

In applications wherein selective deposition is to be performed on patterned wafers, the deposition rate is preferably greater than 3 nm min⁻¹. In certain applications where only silicon and silicon oxide based materials are exposed on the substrate, selectivity is maintained at even higher deposition rates; in one such embodiment, the deposition rate is preferably greater than 5 nm min⁻¹. Selected process conditions that are used in certain embodiments to achieve such deposition rates are listed in Table A. In modified embodiments, PH₃ or B₂H₆ are substituted for AsH₃, although doping with arsenic is advantageous in certain applications because of the lower diffusion constant. Additionally, GeH₄ (1% in H₂) is optionally added to the process gas mixture to produce a silicon germanium film, and/or monomethyl silane is added to the process gas mixture to produce doped Si:C layers.

TABLE A

| | exemplary | |
|---|---|---|
| parameter | value | preferred range |
| temperature (° C.) | 700 | 450 to 750 |
| pressure (torr) | atmospheric | 80 torr to atmospheric |
| H₂ flow (slm) | 10 | 5 to 30 |
| DCS flow (sccm) | 500 | 200 to 2000 |
| AsH₃ flow (sccm) (0.1% in H₂) | 100 | 25 to 1000 |
| HCl flow (sccm) | 50 | 0 to 500 |

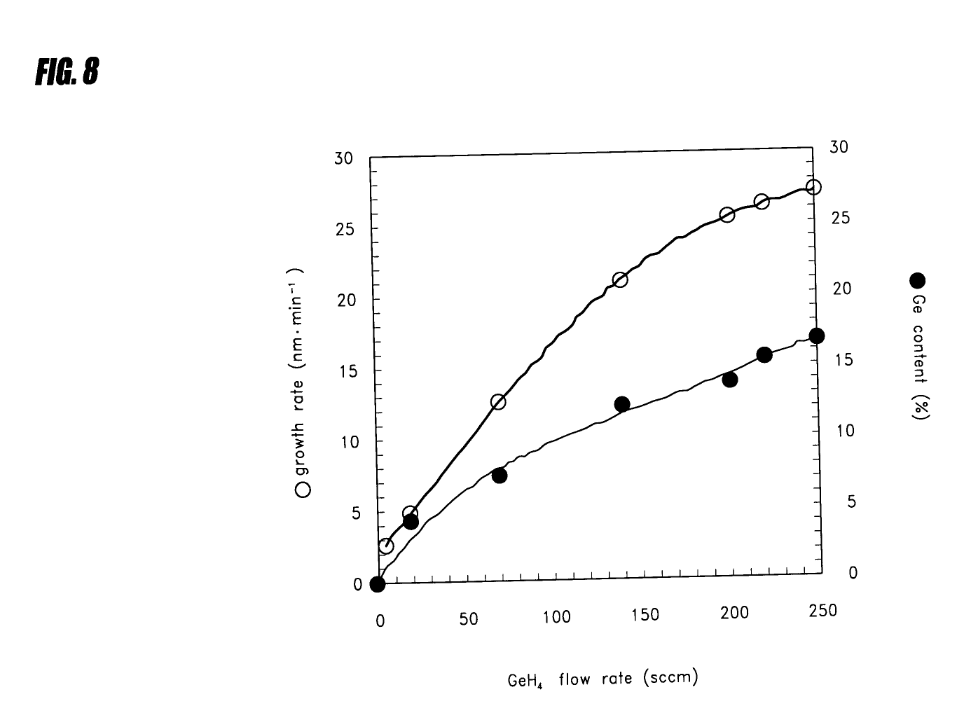

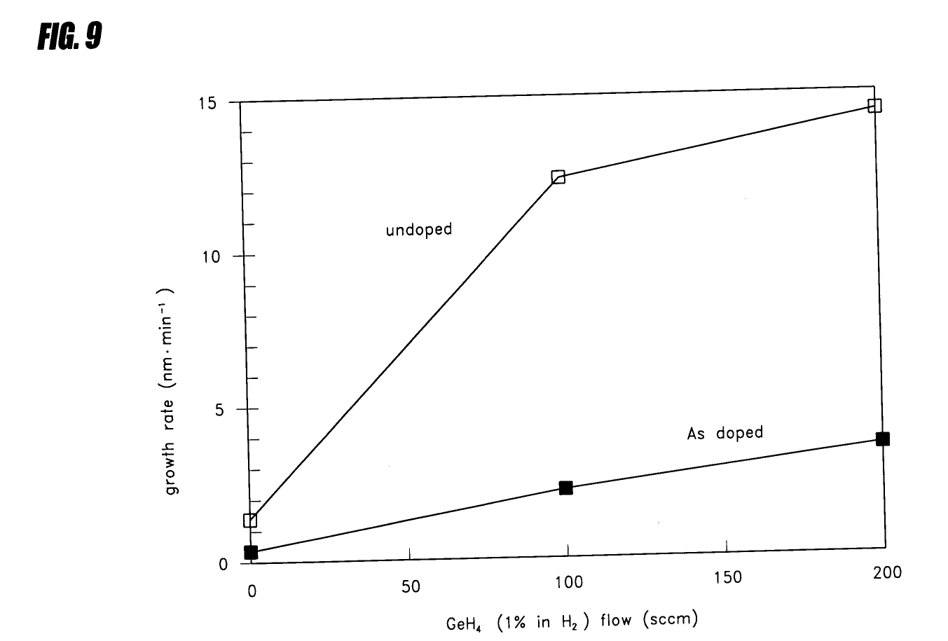

FIG. 8 illustrates growth properties for a epitaxial silicon germanium films selectively grown according to certain embodiments disclosed herein. These films were grown in a chamber at 750° C. and 10 torr. The flow rate of HCl was varied for different GeH₄ flow rates to maintain selectivity. As illustrated, both the incorporation of germanium and the film growth rate increase as the GeH₄ flow rate increases. Addition of AsH₃ to the mixture of process gases reduces the film growth rate, as illustrated in FIG. 9, which illustrates growth rate of a film as a function of GeH₄ flow rate for both non-doped (without AsH₃) and doped (with AsH₃) films. This film was grown in a chamber at 700° C. and 20 torr without any HCl flow.

In certain embodiments, particularly high electrically active dopant concentrations are obtainable. Such embodiments are particularly useful for forming source and drain contacts for transistor structures. Examples of such applications include epitaxial deposition of elevated source and drain structures, as well as of recessed source and drain structures. Furthermore, certain of the embodiments disclosed herein are particularly useful in other applications, such as for forming channel structures and for forming highly doped structures on patterned substrates. Exemplary highly doped structures that are formable using certain of the embodiments disclosed herein include epitaxial emitters for heterojunction bipolar transistors. For example, in one embodiment an epitaxial emitter having high crystal quality, high electrical activation of incorporated dopants, and high growth rate is formed. In such embodiments, after the source and drain structures are formed, a metal deposition is performed which consumes the excess silicon deposited over the source and drain. Thus, the excess silicon deposition prevents or reduces that likelihood that the metal will consume the entire source or drain.

In certain embodiments, highly doped selective deposition is performed under atmospheric conditions using DCS, dopant hydrides, and optionally, HCl to improve selectivity. Optionally, a germanium and/or carbon precursor, such as germane and/or methylsilane, is added to the mixture of precursor gases. In an exemplary embodiment, highly doped selective deposition is performed at a pressure above the RPCVD pressure regime, that is, at a pressure that is preferably greater than about 80 torr. More preferably, such deposition is performed at between about 100 torr and about 760 torr, and most preferably such deposition is performed at about atmospheric pressure.

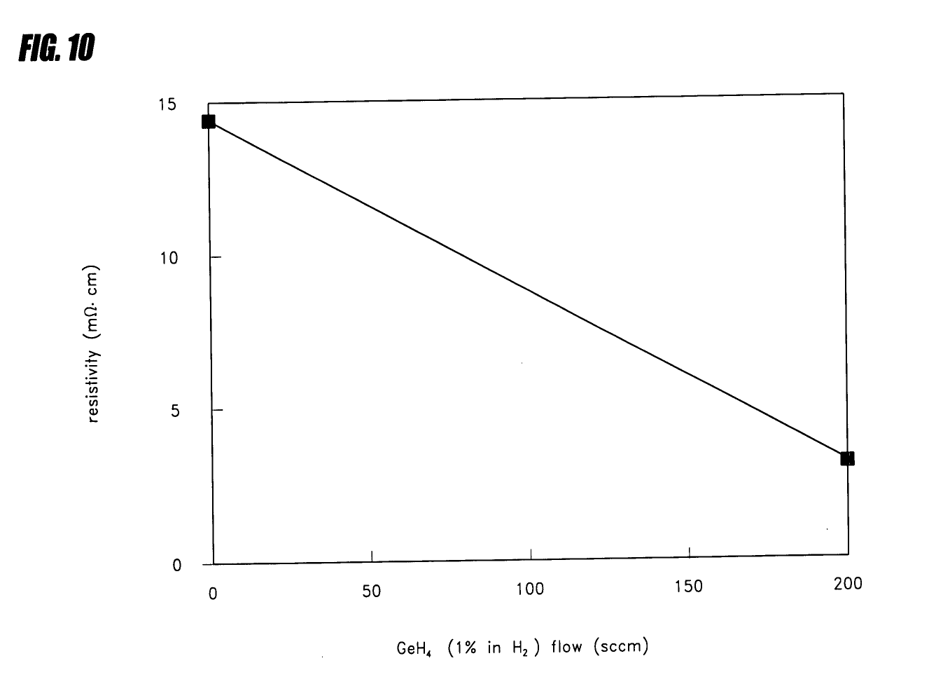

As described herein, in certain embodiments an etchant, such as HCl, is added to the mixture of precursor gases to help maintain or enhance selectively during deposition. In one embodiment wherein selective deposition was performed using a mixture of process gases including HCl, a growth rate between approximately 7 nm min⁻¹ and approximately 8 nm min⁻¹ was obtained, and a film resistivity of approximately 2.5 mΩ cm was obtained. To compensate for the reduction in deposition rate caused by the HCl in the process gas mixture, the temperature is increased with respect to non-selective deposition embodiments. However, the temperature is preferably maintained below approximately 800° C. to maintain good selectivity and to avoid excessive consumption of thermal budget. In a modified embodiment, GeH₄ is added to the process gas mixture to enhance selectivity and growth rate, as illustrated in FIG. 8. Additionally, in embodiments wherein GeH₄ is added to a process gas mixture that includes a dopant hydride, dopant incorporation increases and resistivity decreases with the addition of GeH₄. This effect is evident in FIG. 10, which illustrates resistivity as a function of GeH₄ flow rate. However, in a modified embodiment, an increased growth rate can be obtained without adding germanium. In such embodiments, the deposition pressure is increased and no GeH₄ is supplied to the processing chamber. This increases the film growth rate and decreases the film resistivity by increasing dopant incorporation.

Because arsenic exhibits low diffusivity, sharp transitions from high to low doping levels are possible for n-doping using DCS, particularly at the low process temperatures disclosed herein. Despite these low temperatures, a large proportion of incorporated dopants are electrically active, thereby eliminating separate dopant activation steps and attendant consumption of thermal budget, unwanted diffusion of dopants, and the like. Thus, extremely low resistivity (sheet resistance), superior crystal quality, and low surface roughness can be obtained in certain embodiments.

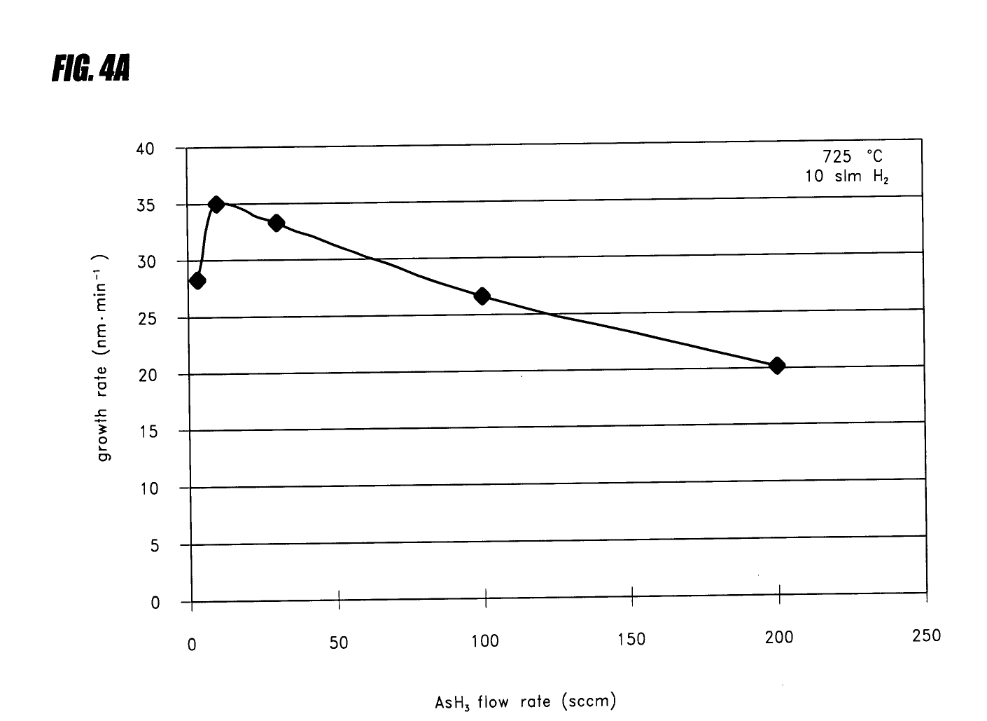

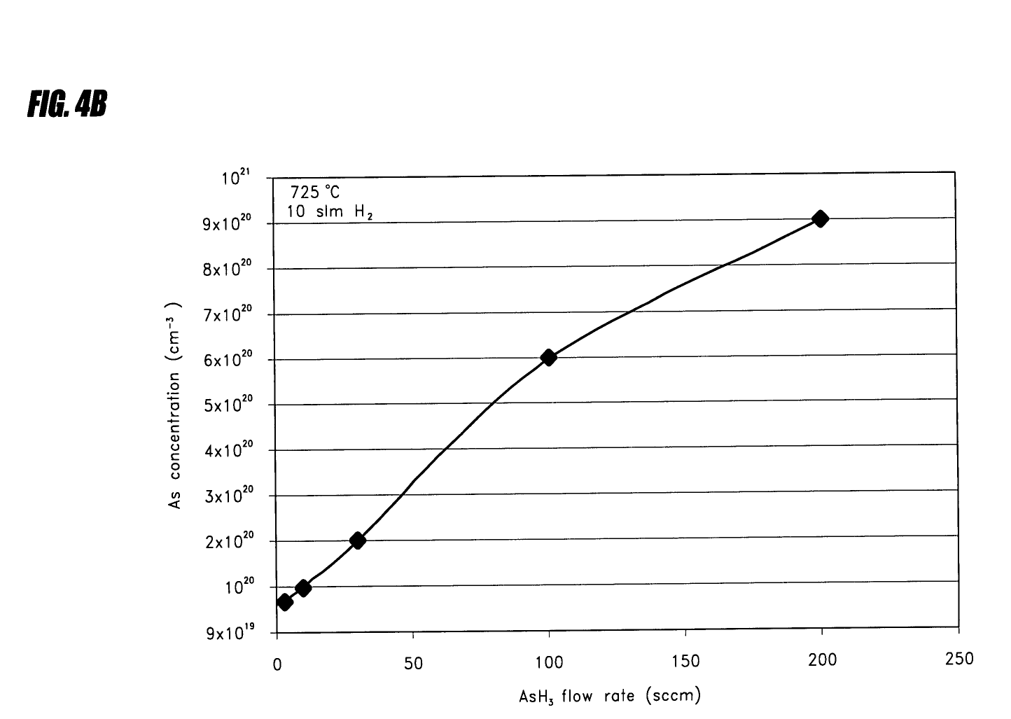

In certain embodiments, a dopant hydride is mixed with DCS to increase deposition rate, as compared to deposition of an undoped (intrinsic) film. HCI is optionally added to the mixture of precursor gases to further enhance selectivity. Even with DCS flow rates up to 1 slm, no saturation of growth rate is observed. Generally, dopant incorporation increases with higher growth rates and higher DCS flow rates, but is unaffected by dopant hydride flow rates. As illustrated in FIG. 4A, in certain embodiments the dopant hydride flow rate is adjusted to optimize the film growth rate. In such embodiments, the dopant hydride flow provides ample removal of chlorine from the film surface without being so high as to adversely affect the film growth rate. Surprisingly, even with a constant flow of dopant hydride, increasing the flow of silicon precursor, for example DCS, advantageously causes growth rate and dopant incorporation to increase. Without being limited by theory, it is believed that this is due to growth rate dependent dopant segregation beahvior and temperature dependent dopant segregation behavior. In a modified embodiment, GeH₄ is added to a process gas mixture that includes a dopant hydride, thereby further improving growth rate, selectivity, faceting and resistivity. In other embodiments, GeH₄ is added to a process gas mixture that does not include a dopant hydride; in such embodiments the GeH₄ enhances growth rate (see FIG. 8), selectivity and faceting while lowering resistivity.

For example, in one embodiment a process gas comprising 1 slm DCS and 10 sccm B₂H₆ (1% in H₂) were supplied to a 630° C. reaction chamber. These process conditions resulted in the growth rates and resistivities provided in Table B.

TABLE B

| H₂ flow rate | growth rate | resistivity |
|---|---|---|
| (slm) | (nm min⁻¹) | (mΩ · cm) |
| 40 | 50 | 6.5 |
| 30 | 64 | 5.1 |
| 20 | 125 | 2.4 |

Certain of the doped films disclosed herein are usable for source and drain contacts, including elevated and recessed contacts, as well as for channels in complementary metal-oxide-semiconductor (“CMOS”) devices and for vertical transistor structures. Vertical transistor structures are sometimes also referred to as double-, tri- and Ω-shaped transistors.

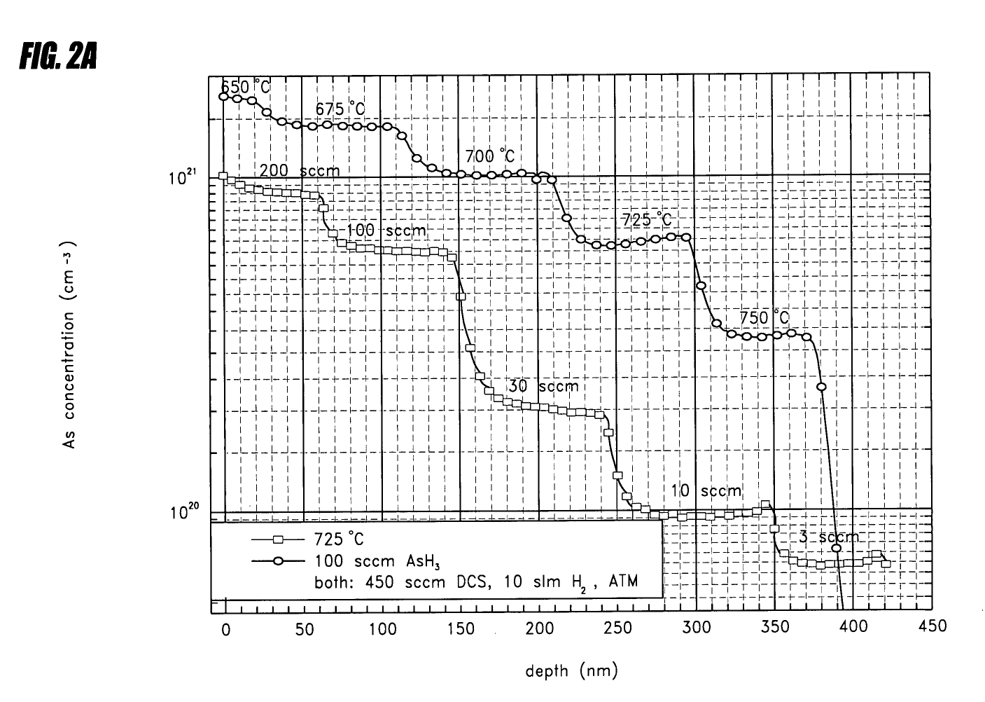

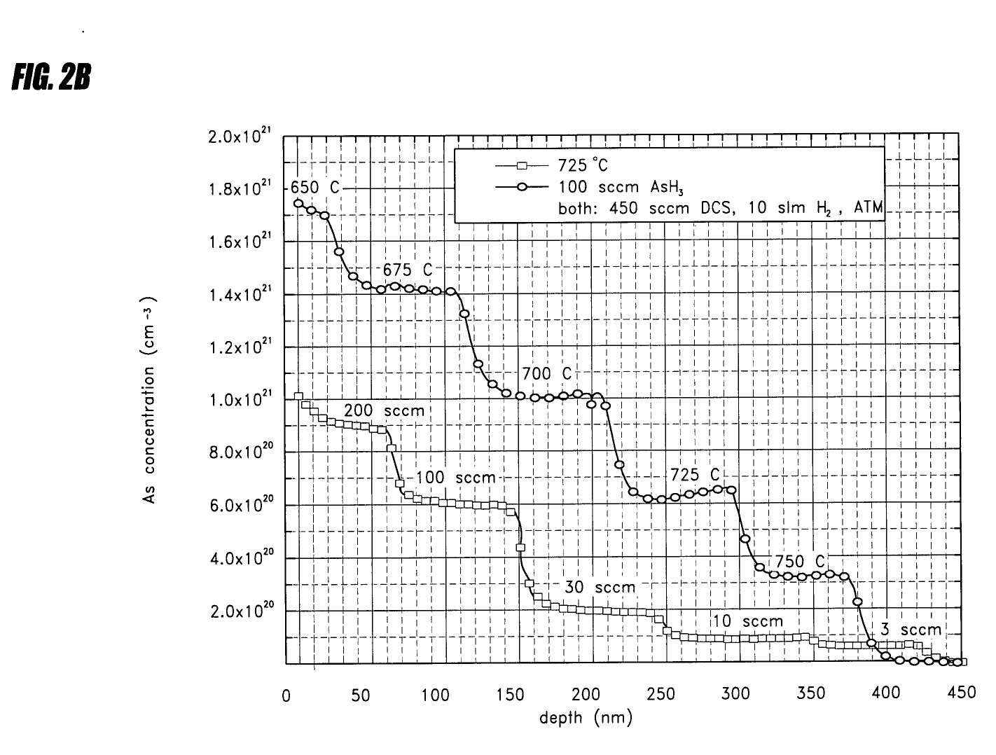

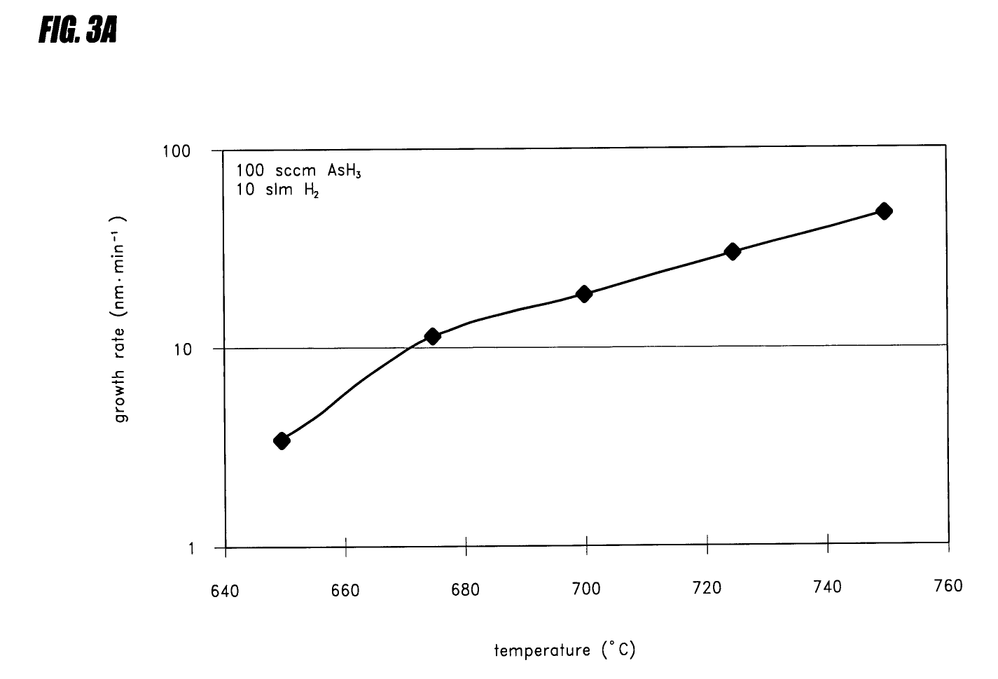

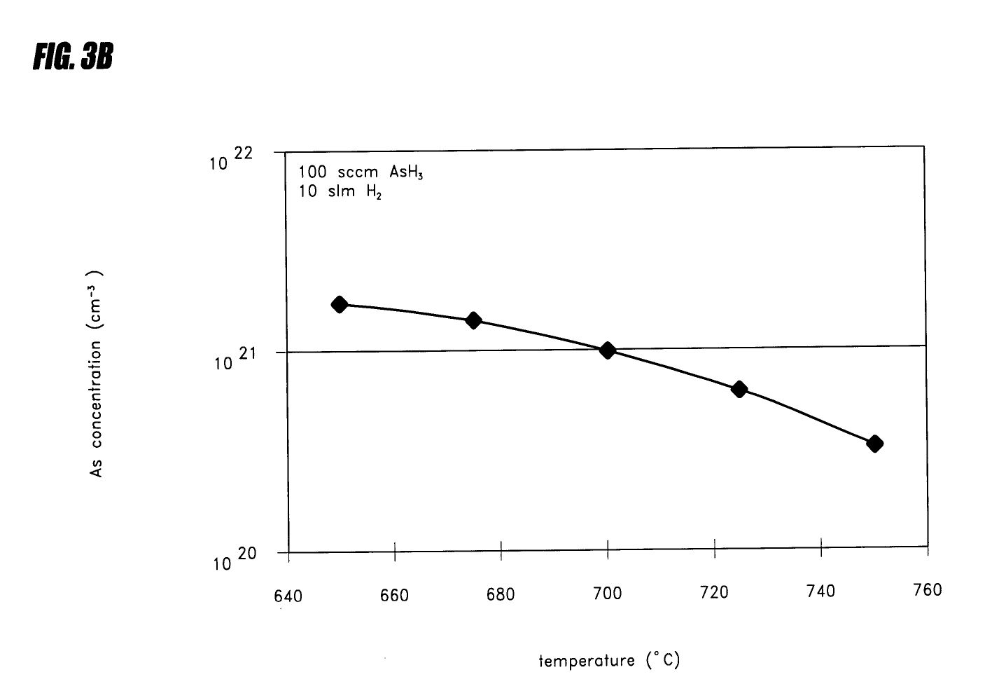

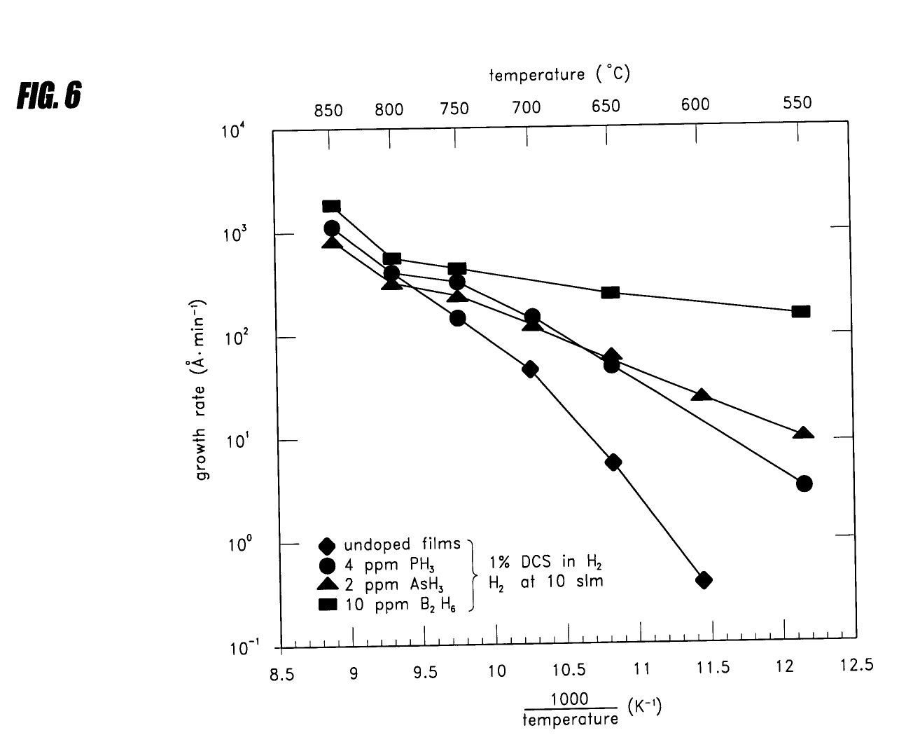

Generally, the films disclosed herein are deposited with process temperatures between about 450° C. and 800° C. FIGS. 2A, 2B, 3A, 3B, 5 and 6, which illustrate selected properties of films grown on 200 mm wafers, show the temperature dependence of certain film properties, such as growth rate, resistivity and dopant concentration. This data shows that when appropriate processing conditions are used, selective in situ doped epitaxial deposition with high dopant incorporation is achievable even at low temperatures. Conventionally, selective epitaxy has been performed at greater than 700° C. for SiGe deposition, and at greater than 750° C. for silicon deposition. Disadvantageously, selective deposition at these high temperatures is slow, and often requires additional dopant activation steps.

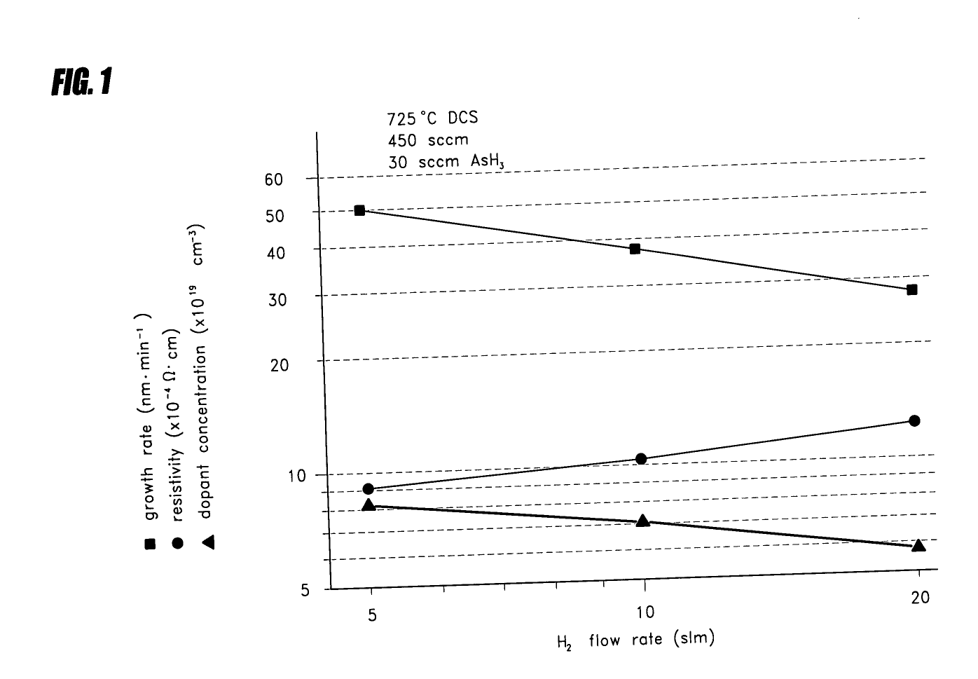

Films deposited in accordance with certain of the embodiments disclosed herein, and specifically at temperatures between approximately 650° C. and approximately 750° C., exhibit improved active dopant concentrations. In certain embodiments, at temperatures less than about 650° C., polycrystalline deposition becomes dominant, causing resistivity to increase dramatically, as illustrated in FIG. 5. In a preferred embodiment, films having an active dopant concentration between approximately 10¹⁹ cm⁻³ and approximately 2×10²¹ cm⁻³ are deposited. This results in an as-deposited resistivity that is preferably about 1 m Ω·cm or less, and is more preferably about 0.8 m Ω·cm or less. An as-deposited resistivity of about 0.8 mΩ cm roughly corresponds to an active doping concentration of about 10²⁰ cm⁻³. These values are approaching the solid solubility limits of arsenic. In such embodiments, the total arsenic concentration does not saturate when the dopant flow is adjusted, in contrast to the electrically active dopant concentration. See also FIG. 1, which illustrates growth rate, resistivity and dopant concentration for deposition of in situ doped films grown on 200 mm wafers using selected processing conditions. FIG. 1 also illustrates that, at higher growth rates, electrically active dopant incorporation increases, thereby decreasing film resistivity.

In certain embodiments, in situ doped semiconductor films can be deposited at pressures greater than 100 torr and at temperatures between approximately 450° C. and approximately 600° C. Deposition within this lower temperature regime advantageously reduces consumption of thermal budget and increases the proportion of electrically active dopants incorporated into the semiconductor film.

In a modified embodiment, carbon doped silicon epitaxial layers are deposited using DCS and dopant hydrides such as arsine (AsH₃) or phosphine (PH₃). The smaller carbon atoms create more room for large dopant atoms or germanium atoms. For example, silicon germanium with about 10% germanium content tends to be compressively strained when heteroepitaxially deposited over single crystal silicon. However, the addition of 1% carbon will create enough room in the lattice structure for the overall Si_{0.89}Ge_{0.10}C_{0.01} layer to be effectively unstrained. Similarly, for a given level of tensile strain, incorporation of carbon into the lattice structure permits incorporation of a greater concentration of electrically active dopants. For such a process, a small amount of organic silicon precursor, such as monomethyl silane, is added to the DCS flow as a source for silicon and carbon. The doped Si:C layers formed using such embodiments have applications in the formation of source and drain contact structures.

Using DCS and either arsine or phosphine as precursors for in situ doped epitaxial deposition, and using higher DCS flow rates for a given dopant hydride flow rate, tends to increase the rate of incorporation of active dopants into the film. Without being limited by theory, it is believed that increased dopant concentration is due to the increased deposition rate. In particular, it is believed that the dopants do not have time to segregate by diffusion to the surface of the growing film. Therefore, the dopants do not have the opportunity to block or inhibit deposition, as they quickly get buried by the high flow rates of silicon precursor. Accordingly, for single wafer deposition, the DCS flow rate preferably exceeds 200 sccm, and more preferably is between approximately 300 sccm and approximately 5 slm. Higher flow rates are used in other embodiments. In certain embodiments, the ratio of DCS flow rate to dopant hydride flow rate (R_{DCS:DH}) varies depending on the temperature range. Preferably, at temperatures below about 675° C., a higher R_{DCS:DH} is used (for example, between about 50:1 and about 100:1), whereas at temperatures above about 675° C., a lower R_{DCS:DH} is used (for example, between about 4:1 and about 50:1).

FIG. 4A illustrates growth rate as a function of dopant hydride flow rate for a semiconductor film deposited on a 200 mm wafer at atmospheric pressure. As illustrated, increasing the dopant hydride flow rate increases the growth rate up to a point, after which further increases in dopant hydride flow rate decrease the overall film growth rate. The maximum growth rate generally occurs at a higher level of dopant hydride flow at higher temperatures. The maximum growth rate also generally increases with temperature. Similarly, increasing the DCS flow rate also increases the maximum growth rate. FIG. 4B illustrates dopant concentration as a function of dopant hydride flow rate under the same processing conditions as FIG. 4A.

In certain of the examples disclosed herein, the substrates are processed in a single wafer chamber, such as a 200 mm Epsilon® single wafer epitaxial deposition reactor, commercially available from ASM America, Inc. (Phoenix, Ariz.). In an exemplary embodiment, the substrate is a 200 mm Si (001) wafer that is cleaned to remove native oxide before performing the deposition processes disclosed herein. An example cleaning process for wafers on which deposition is to be performed comprises performing an in situ bake at about 1050° C. An example cleaning process for patterned wafers on which selective deposition is to be performed comprises an HF dip followed by a deionizing rinse, a Marangoni dry, and an in situ bake at between about 850° C. and about 900° C.

In one embodiment, where deposition is to be formed on a 200 mm wafer, between approximately 200 sccm and approximately 3 sim of DCS is provided to the reaction chamber with between approximately 10 sccm and approximately 100 sccm arsine (1% in H₂). In other embodiments, different factors can be compensated by commensurate changes in reactant flow rates. For example, higher flow rates are generally employed for deposition on larger substrates, such as 300 mm wafers. Stated more generally, for single wafer processing, preferably between about 5 sccm and about 200 sccm of 1% dopant hydride in a diluent (for example, H₂) is provided, which is substantially equivalent to between about 50 sccm and about 2000 sccm of 0.1% dopant hydride in H₂, or about 0.05 sccm and 2 sccm of pure arsine.

An additional advantage of the chemistries described herein is a lack of loading effects. Few if any loading effects are detectable across the wafer surface when certain of the embodiments disclosed herein are employed. Nonuniformities were found to be about the same from window to window across the wafer surface despite differences in window sizes. Thus, the average nonuniformity for a window of ×cm² will differ by less than about 5% from the average nonuniformity of a window with about (0.5)×cm².

Furthermore, micro-loading effects are also reduced when certain of the embodiments disclosed herein are used. In the context of selective deposition on a patterned wafer, micro-loading effects refer to local deposition pattern nonuniformities in growth rate and film composition within the patterned windows on the wafer surface. For example, faceting is a micro-loading effect that causes a thinning of the epitaxial layer around the edges of a selective deposition pattern. Faceting disadvantageously complicates self-aligned salicidation or “salicidation” steps that are performed after an epitaxial deposition. In certain embodiments, reducing the deposition pressure and/or reducing the deposition temperature helps to reduce or eliminate micro-loading effects. In one embodiment, within one window, less than 20% nonuniformity is present across any given window.

It should be noted that certain objects and advantages of selected embodiments have been described above for the purpose of describing the invention and the advantages achieved over the prior art. Not necessarily all such objects or advantages are achieved with respect to any particular embodiment. Thus, for example, certain embodiments can be embodied or carried out in a manner that achieves or optimizes one advantage or group of advantages without necessarily achieving other objects or advantages.

1. A method for depositing an in situ doped epitaxial semiconductor layer, comprising:
maintaining a pressure of greater than about 80 torr in a process chamber housing a patterned substrate;
providing a flow of dichlorosilane to the process chamber;
providing a flow of a dopant hydride to the process chamber; and
selectively depositing the epitaxial semiconductor layer on single crystal material on the patterned substrate at a rate of greater than about 3 nm min⁻¹.

2. The method of claim 1, wherein the epitaxial semiconductor layer has a dopant concentration of greater than about 10¹⁹ cm⁻³.

3. The method of claim 1, wherein the epitaxial semiconductor layer has a dopant concentration of between about 10¹⁹ cm⁻³ and about 2×10²¹ cm⁻³.

4. The method of claim 1, wherein the patterned substrate comprises exposed silicon oxide based insulating material and selectively depositing comprises deposition at a rate greater than about 5 nm min⁻¹.

5. The method of claim 1, wherein the flow of dichlorosilane is greater than about 200 sccm.

6. The method of claim 1, wherein the flow of dichlorosilane is between about 300 sccm and about 5 slm.

7. The method of claim 1, wherein the ratio of the flow of dichlorosilane to the flow of the dopant hydride (diluted 1% in a diluent gas) is between about 4:1 and about 100:1, or equivalent for different dilutions of the dopant hydride.

8. The method of claim 1, wherein the ratio of the flow of dichlorosilane to the flow of the dopant hydride (diluted 1% in a diluent gas) is between about 50:1 and about 100:1, or equivalent for different dilutions of the dopant hydride.

9. The method of claim 1, wherein the ratio of the flow of dichlorosilane to the flow of the dopant hydride (diluted 1% in a diluent gas) is between about 4:1 and about 50:1, or equivalent for different dilutions of the dopant hydride.

10. The method of claim 1, further comprising maintaining a pressure of greater than about 100 torr in the process chamber during deposition.

11. The method of claim 1, further maintaining a pressure of about atmospheric pressure in the process chamber during deposition.

12. The method of claim 1, further comprising flowing an etchant while selectively depositing.

13. The method of claim 12, wherein the etchant comprises HCl.

14. The method of claim 1, wherein selectively depositing exhibits loading effects less than a loading effect in which an average nonuniformity for a window of ×cm² differs by about 5% from an average nonuniformity for a window of (0.5)×cm².

15. The method of claim 1, wherein selectively depositing exhibits micro-loading effects with less than 20% nonuniformity within a given semiconductor window on the substrate.

16. The method of claim 1, further comprising flowing a carbon precursor with the dichlorosilane and the dopant hydride and incorporating carbon into the epitaxial semiconductor layer.

17. The method of claim 16, wherein the carbon precursor comprises an organic silicon precursor.

18. The method of claim 16, wherein the carbon precursor comprises methylsilane.

19. The method of claim 1, further comprising flowing a germanium precursor with the dichlorosilane and the dopant hydride and incorporating germanium into the epitaxial semiconductor layer.

20. The method of claim 19, wherein the germanium precursor comprises germane.

21. The method of claim 1, wherein the dopant hydride comprises arsine.

22. The method of claim 21, where the flow of the dopant hydride is between about 5 and about 200 sccm of arsine (diluted 1% in a diluent gas) or equivalent for different dilutions of arsine.

23. The method of claim 1, wherein the dopant hydride comprises phosphine.

24. A method of forming contacts for a transistor structure, the method comprising:
providing a substrate having a defined source active area and a defined drain active area; and
exposing the source and drain active areas to a precursor mixture including dichlorosilane, a dopant hydride and an etchant gas, thereby selectively depositing an in situ doped epitaxial semiconductor layer on the source and drain active areas.

25. The method of claim 24, wherein exposing comprises maintaining a deposition pressure greater than about 100 torr.

26. The method of claim 24, wherein exposing comprises providing greater than about 200 sccm dichlorosilane to a single wafer deposition chamber.

27. The method of claim 24, wherein the epitaxial semiconductor layer has an as-deposited resistivity less than about 1 m Ω·cm.

28. The method of claim 24, wherein the epitaxial semiconductor layer has an as-deposited resistivity less than about 0.8 m Ω·cm.

29. The method of claim 24, wherein the active areas comprise recesses.

30. The method of claim 24, wherein exposing comprises maintaining a deposition temperature between about 650° C. and about 750° C.

31. The method of claim 24, wherein exposing comprises maintaining a deposition temperature between about 450° C. and about 650° C.

32. The method of claim 24, wherein the etchant gas comprises HCl.

33. A process for depositing silicon containing layers, comprising:
providing a chamber at a pressure greater than about 100 torr;
flowing dichlorosilane and a dopant hydride over a substrate housed in the chamber; and
epitaxially depositing a silicon containing layer on the substrate at rate of greater than about 25 nm min⁻¹.

34. The method of claim 33, wherein the dopant hydride is an n-type dopant hydride.

35. The method of claim 33, wherein the silicon containing layer has a dopant concentration of greater than about 10¹⁹ cm⁻³.

36. The method of claim 33, wherein the silicon containing layer has a dopant concentration of between about 10¹⁹ cm⁻³ and about 2×10²¹ cm⁻³.

37. The method of claim 33, wherein the epitaxial deposition is a selective deposition.

38. The method of claim 33, wherein the silicon containing layer has an as-deposited resistivity less than about 1 m Ω·cm.

39. The method of claim 33, wherein the silicon-containing layer has an as-deposited resistivity less than about 0.8 mΩ·cm.
